(19) United States
(12) Patent Application Publication
(10) Pub. No.: US 2026/0127990 A1
(43) Pub. Date: May 7, 2026

(54) ELECTRONIC DEVICE AND DETECTION METHOD THEREOF

(71) Applicant: InnoLux Corporation, Miao-Li County (TW)

(72) Inventors: Chieh-Chung PENG, Miao-Li County (TW); Wei-Sheng KAO, Miao-Li County (TW); Yi-Dan OU, Miao-Li County (TW)

(21) Appl. No.: 19/349,181

(22) Filed: Oct. 3, 2025

(30) Foreign Application Priority Data
Nov. 4, 2024 (CN) 202411557598.4

(51) Int. Cl. G09G 3/00; G01R 31/28

(52) U.S. Cl. CPC G09G 3/006; G01R 31/2837; G01R 31/2839; G01R 31/2844; G09G 2300/0426

(57) ABSTRACT

An electronic device is provided. The substrate includes an active area and a peripheral area surrounding the active area. The first signal transmission signal line and the control signal line are disposed in the peripheral area. The first common voltage lines are disposed in the active area. The first switch components are coupled between the first common voltage lines and the first signal transmission line. In a display mode, the circuit board provides a first voltage to the first switch components through the control line, and the first common voltage lines are coupled to the first signal transmission line. In a sensing mode, the driving chip provides a sensing signal to the first common voltage lines, the circuit board provides a second voltage to the first switch components through the control line, and the first common voltage lines are not coupled to the first signal transmission line.

### CROSS REFERENCE TO RELATED APPLICATIONS

This application claims priority of China Patent Application No. 202411557598.4, filed on Nov. 4, 2024, the entirety of which is incorporated by reference herein.

### BACKGROUND OF THE DISCLOSURE

### Field of the Disclosure

The disclosure relates to an electronic device, and in particular, it relates to an electronic device and a detection method thereof.

### Description of the Related Art

In a conventional sensing display device, there is a configuration of partitioned common electrodes. In display mode, the above partitioned common electrodes may take on the role of receiving and providing a common voltage. In sensing mode, the above partitioned common electrodes may serve as sensing electrodes for sensing capacitance differences. However, the partitioned common electrodes in the sensing display device may not be short-circuited with each other, otherwise the sensing function of the sensing display device may be affected. Therefore, a new design is needed to solve the problem described above.

### BRIEF SUMMARY OF THE DISCLOSURE

An embodiment of the disclosure provides an electronic device having a display mode and a sensing mode. The electronic device includes a panel and a circuit panel. The panel includes a substrate, a first signal transmission line, a control line, a plurality of first common voltage lines, a plurality of first switch components and a driving chip. The substrate includes an active area and a peripheral area surrounding the active area. The first signal transmission line is disposed in the peripheral area. The control line is disposed in the peripheral area. The first common voltage lines are disposed in the active area. The first switch components are coupled between the first common voltage lines and the first signal transmission line. The driving chip is coupled to the first common voltage lines. The circuit panel is coupled to the control line. In the display mode, the circuit board provides a first voltage to the first switch components through the control line, so that the first common voltage lines are coupled to the first signal transmission line. In the sensing mode, the driving chip provides a sensing signal to the first common voltage lines, the circuit board provides a second voltage to the first switch components through the control line, so that the first common voltage lines are not coupled to the first signal transmission line.

An embodiment of the disclosure provides a detection method of an electronic device, which includes the following steps. A panel is provided, wherein the panel includes a first common voltage line, a second common voltage line, a control line, a first switch component, a second switch component, a first signal transmission line and a second signal transmission line. The control line is used provide a first voltage to the first switch component and the second switch component, so that the first common voltage line is coupled to the first signal transmission line, and the second common voltage line is coupled to the second signal transmission line. A first testing voltage is provided to the first signal transmission line and a second testing voltage is provided to the second signal transmission line, so that the panel displays a testing pattern. It is determined whether the testing pattern matches a predetermined pattern. When determining that the testing pattern matches the predetermined pattern, a detection normal message is generated. When determining that the testing pattern does not match the predetermined pattern, a detection error message is generated.

### BRIEF DESCRIPTION OF THE DRAWINGS

The disclosure can be fully understood by reading the subsequent detailed description and examples with references made to the accompanying drawings, wherein:

FIG. 1 is a schematic view of an electronic device according to an embodiment of the disclosure;

FIG. 2 is a schematic view of an electronic device according to another embodiment of the disclosure;

FIG. 3 is a schematic view of an electronic device according to another embodiment of the disclosure;

FIG. 4 is a schematic view of a structure of an electronic device according to an embodiment of the disclosure;

FIG. 5 is a cross-sectional view of an active area of FIG. 4;

FIG. 6 is a schematic view of a line layout of a first signal transmission line, a second signal transmission line, a control line and a circuit board according to an embodiment of the disclosure;

FIG. 7 is a schematic view of a line layout of a first signal transmission line, a second signal transmission line, a control line, a plurality of first switch components, a plurality of second switch components and a circuit board according to an embodiment of the disclosure; and

FIG. 8 is a flowchart of a detection method of an electronic device according to an embodiment of the disclosure.

### DETAILED DESCRIPTION OF THE DISCLOSURE

In order to make objects, features and advantages of the disclosure more obvious and easily understood, the embodiments are described below, and the detailed description is made in conjunction with the drawings. In order to help the reader to understand the drawings, the multiple drawings in the disclosure may depict a part of the entire device, and the specific components in the drawing are not drawn to scale.

The specification of the disclosure provides various embodiments to illustrate the technical features of the various embodiments of the disclosure. The configuration, quantity, and size of each component in the embodiments are for illustrative purposes, and are not intended to limit the disclosure. In addition, if the reference number of a component in the embodiments and the drawings appears repeatedly, it is for the purpose of simplifying the description, and does not mean to imply a relationship between different embodiments.

Furthermore, use of ordinal terms such as “first”, “second”, etc., in the specification and the claims to describe a claim element does not by itself connote and represent the claim element having any previous ordinal term, and does not represent the order of one claim element over another or the order of the manufacturing method, either. The ordinal terms are used as labels to distinguish one claim element having a certain name from another element having the same name.

In the disclosure, the technical features of the various embodiments may be replaced or combined with each other to complete other embodiments without being mutually exclusive.

In some embodiments of the disclosure, unless specifically defined, the term “connected” or “coupled” or “electrically connected” may include any direct and indirect means of electrical connection.

In the text, the terms “substantially” or “approximately” usually means within 20%, or within 10%, or within 5%, or within 3%, or within 2%, or within 1%, or within 0.5% of a given value or range. The quantity given here is an approximate quantity. That is, without the specific description of “substantially” or “approximately”, the meaning of “substantially” or “approximately” may still be implied.

The “including” mentioned in the entire specification and claims is an open term, so it should be interpreted as “including or comprising but not limited to”.

In an embodiment, the electronic device may include a display device, a sensing device, but the disclosure is not limited thereto. The electronic device may be a bendable or flexible electronic device. The display device may be a non-self-luminous type display device or a self-luminous type display device. The sensing device may be a sensing device that senses capacitance, light, heat or ultrasound, but the disclosure is not limited thereto. The electronic component may include a passive component and an active component, such as a capacitor, a resistor, an inductor, a diode, a transistor, etc. The diode may include a light-emitting diode or a photodiode. The light-emitting diode may include, for example, an organic light-emitting diode (OLED), a mini LED, a micro LED or a quantum dot LED, but the disclosure is not limited thereto. It should be noted that the electronic device may be any arrangement and combination of the above devices, but the disclosure is not limited thereto.

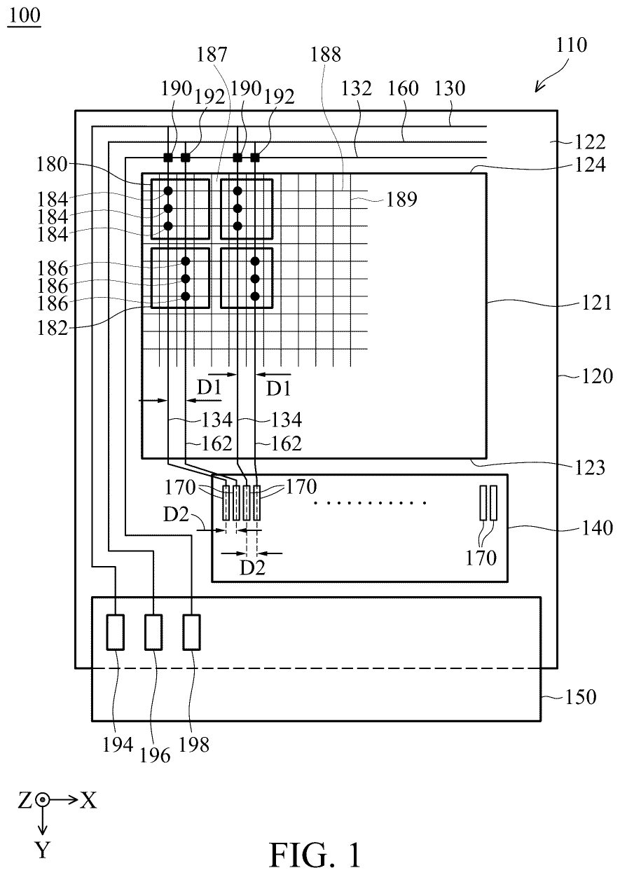

FIG. 1 is a schematic view of an electronic device according to an embodiment of the disclosure. In the embodiment, the electronic device 100 may at least have a display mode and a sensing mode. In an embodiment, the sensing in the sensing mode may include an image sensor, a pressure sensor, a temperature sensor, a gas sensor, a touch sensor, a torque sensor, an ultrasonic sensor, an angular velocity sensor, but the disclosure is not limited thereto. In the embodiment, the sensing in the sensing mode may be explained by taking touch as an example, but the disclosure is not limited thereto. In addition, the electronic device 100 may be a touch in display (TID) device, but the disclosure is not limited thereto. Please refer to FIG. 1. The electronic device 100 may at least include a panel 110 and a circuit board 150.

In some embodiment, the panel 110 may be a touch in display panel, but the disclosure is not limited thereto. The panel 110 may at least include a substrate 120, a first signal transmission line 130, a control line 132, a plurality of first common voltage lines 134 and a driving chip 140.

The substrate 120 may include an active area (AA) 121 and a peripheral area 122 adjacent to (for example, surrounding) the active area 121. In some embodiments, the substrate 120 may a rigid substrate or a flexible substrate, and the material of the substrate 120 may include glass, quartz, sapphire, ceramics, polycarbonate (PC), polyimide (PI), polyethylene terephthalate (PET), other suitable materials or a combination thereof, but the disclosure is not limited thereto.

The first signal transmission line 130 may be disposed in the peripheral area 122. In some embodiments, at least one portion of the first signal transmission line 130 may extend in a first direction, and another portion of the first signal transmission line 130 may be extend in a second direction. In addition, the first direction may be a X direction, and the second direction may be a Y direction, but the disclosure is not limited thereto. The control line 132 may be disposed in the peripheral are 122. In some embodiments, the control line 132 may be used to control whether the switch component is turned on. When the switch component is turned on, the first signal transmission line 130 and the second signal transmission line 160 may be used to transmit the signal to the active are 121. In some embodiments, at least one portion of the control line 132 may be extend in the first direction, and another portion of the control line 132 may extend in the second direction. In some embodiments, the first signal transmission line 130 may be disposed adjacent to the control line 132. The first common voltage lines 134 may be disposed on the substrate 120. In some embodiments, the first common voltage lines 134 may extend in the second direction. In the embodiments, the first common voltage lines 134 and the data lines 189 do not overlap each other, so as to reduce the formation of capacitance, but the disclosure is not limited thereto. In other embodiments, the first common voltage lines 134 and the data lines 189 may also overlap, so as to increase the aperture ratio.

The driving chip 140 may be disposed in the peripheral area 122. The circuit board 150 may at least partially overlap the peripheral area 122. In some embodiments, the circuit board 150 may be located on the side surface of the panel, but the disclosure is not limited thereto. In some embodiments, the driving chip 140 may be located between the active area 121 and the circuit board 150, but the disclosure is not limited thereto. In some embodiments, the circuit board 150 may be a flexible printed circuit (FPC) board, but the disclosure is not limited thereto.

In a top view, at least one portion of the first common voltage lines 134 may be located in the active area 121, and another portion of the first common voltage lines 134 may extend outside the active area 121 and be located in the peripheral area 122. The circuit board 150 may be coupled to the control line 132. In addition, the circuit board 150 may also be coupled to the first signal transmission line 130. Furthermore, the driving chip 140 may be coupled to the first common voltage lines 134.

As shown in Table 1, in the display mode, the circuit board 150 may provide a first voltage to the control line 132, so that the first common voltage lines 134 may be coupled to the first signal transmission line 130, and the circuit board 150 may provide a common voltage to the first signal transmission line 130 and the first common voltage lines 134.

As shown in Table 1, in the touch mode, the driving chip 140 may provide a sensing signal to the first common voltage lines 134, and the circuit board 150 may provide a second voltage to the control line 132, so that the first common voltage lines 134 are not coupled to the first signa transmission line 130. Therefore, the effect of signal difference of the first common voltage lines 134 may be reduced, or the display unevenness (Mura) caused by the signal difference may be reduced. In some embodiments, the first voltage may be different from the second voltage. Furthermore, the first voltage may be a high voltage, and the second voltage may be a low voltage, but the disclosure is not limited thereto.

TABLE 1

| | display mode | sensing mode |
|---|---|---|
| the control line 132 | first voltage | second voltage |
| the first signal transmission | common voltage | not coupled (NC) |
| line 130 | | |
| the second signal | common voltage | not coupled (NC) |
| transmission line 160 | | |
| the first common voltage | common voltage | sensing voltage |
| line 134 | | |
| the second common voltage | common voltage | sensing voltage |
| line 162 | | |

In some embodiments, the electronic device 100 may further include a second signal transmission line 160 and a plurality of second common voltage lines 162. The second signal transmission line 160 may be disposed in the peripheral area 122 and coupled to the circuit board 150. In some embodiments, at least one portion of the second signal transmission 160 may extend in the first direction, and another portion of the second signal transmission line 160 may extend in the second direction. In some embodiments, in the top view, the second signal transmission line 160 may be located between the first signal transmission line 130 and the control line 132, wherein the first signal transmission line 130 may be regarded as an odd signal transmission line, and the second signal transmission line 160 may be regarded as an even signal transmission line, so as to generate a checkerboard testing pattern described later, but the disclosure is not limited thereto.

The second common voltage lines 162 may be disposed on the substrate 120. In some embodiments, the second common voltage lines 162 may extend in the second direction. In some embodiments, in the top view, at least one portion of the second common voltage lines 162 may be located in the active area 121, and another portion of the second common voltage lines 162 may extend outside the active area 121 and be located in the peripheral area 122. In addition, one of the second common voltage lines 162 may be located between two of the first common voltage lines 134 adjacent to each other. That is, the first common voltage lines 134 and the second common voltage lines 162 may be alternately disposed sequentially on the substrate 120 in the first direction. Furthermore, the second common voltage lines 162 may be coupled to the driving chip 140.

In the display mode, the second common voltage lines 162 may be coupled to the second signal transmission line 160, and the circuit board 150 may provide the common voltage to the second signal transmission line 160 and the second common voltage lines 162. That is, as shown in Table 1, in the display mode, the circuit board 150 may provide the first voltage to the control line 132, so that the first common voltage lines 134 may be coupled to the first signal transmission line 130 and the second common lines 162 may be coupled to the second signal transmission line 160, and the circuit board 150 may provide the common voltage to the first signal transmission line 130 and the first common voltage lines 134 and the second signal transmission line 160 and the second common voltage lines 162.

In addition, in the sensing mode, the second common voltage lines 162 are not coupled to the second signal transmission line 160. That is, as shown in Table 1, in the sensing mode, the driving chip 140 may provide the sensing signal to the first common voltage lines 134 and the second common voltage lines 162, the circuit board 150 may provide the second voltage to the control line 132, so that the first common voltage lines 134 are not coupled to the first signal transmission line 130 and the second common voltage lines 162 are not coupled to the second signal transmission line 160. Therefore, the effect of signal difference of the first common voltage lines 134 and the second common voltage lines 162 may be reduced, or the display unevenness caused by the signal difference may be reduced.

In some embodiments, the electronic device 100 may further include a plurality of connection pads 170. The connection pads 170 may be disposed on the substrate. 120, and the connection pads 170 may at least partially overlap the driving chip 140. In addition, the first common voltage lines 134 and the second common voltage lines 162 may be coupled to the driving chip 140 through the connection pads 170. That is, the sensing signal provided by the driving chip 140 may be transmitted to the first common voltage lines 134 and the second common voltage lines 162 through the connection pads 170.

In some embodiments, in the top view, the connection pads 170 may be adjacent to the first side 123 of the active area 121, the first signal transmission line 130, the second signal transmission line 160 and the control line 132 may be adjacent to the second side 124 of the active area 121, and the first side 123 may be opposite to the second side 124. In addition, in some embodiments, the peripheral area 122 adjacent to the second side 124 of the active area 121 may be an anti-terminal side, i.e., the first signal transmission line 130, the second signa transmission line 160 and the control line 132 may be disposed on the anti-terminal side, but the disclosure is not limited thereto. Furthermore, in some embodiments, the driving chip 140 may be located between the first side 123 of the active area 121 and the circuit board 150.

In some embodiments, the electronic device 100 may at least include a first common electrode 180 and a second common electrode 182. The first common electrode 180 and the second common electrode 182 may be disposed in the active area 121. The first common electrode 180 may be adjacent to the second common electrode 182. The first common electrode 180 may be coupled to one of the first common voltage lines 134 through a plurality of first vias 184. The second common electrode 182 may be coupled to one of the second common voltages 162 through a plurality of second vias 186.

In some embodiments, the electronic device 100 may further include a plurality of pixels 187, a plurality of scan lines 188 and a plurality of data lines 189. The pixels 187 may be disposed on the substrate 120 and be located in the active area 121. Furthermore, the pixels 187 may be arranged in a matrix in the active area 121. In addition, in some embodiments, in the top view, the distance between two adjacent first common electrodes 180 does not exceed the width of one of the pixels 187, and the distance between two adjacent second common electrodes 182 does not exceed the width of one of the pixels 187.

In the embodiment, the pixels 187 are non-self-luminous and includes at least a portion of a modulation dielectric layer, a common electrode layer and a pixel electrode (as shown in FIG. 5), but the disclosure is not limited thereto. In other embodiments, the pixels 187 are self-luminous and may include a light emitting diode, but the disclosure is not limited thereto. The scan lines 188 may be disposed on the substrate 120 and located in the active area 121, and the scan lines 188 may extend along the first direction. The data lines 189 may disposed on the substrate 120 and located in the active area 121, and the data lines 189 may extend along the second direction. In the embodiments, the pixels 187 may be an area enclosed by the data lines 189 and the scan lines 188.

In some embodiments, in the display mode, the first common electrode 180 and the second common electrode 182 may be used as electrodes receiving the common voltage. In the sensing mode, the first common electrode 180 and the second common electrode 182 may be used as electrodes receiving the sensing voltage.

In some embodiments, the electronic device 100 further include a plurality of first switch components 190 and a plurality of second switch components 192. One of the first switch components 190 may be coupled to the first signal transmission line 130, the control line 132 and one of the first common voltage lines 134. Furthermore, each of the first switch component 190 may include a first terminal, a second terminal and a control terminal. The first terminals of the first switch components 190 may be coupled to the first signal transmission line 130. The second terminals of the first switch components 190 may be coupled to the first common voltage lines 134. The control terminals of the first switch components 190 may be coupled to the control line 132.

In the display mode, the circuit board 150 may provide the first voltage (such as the high voltage) to the control line 132, and the first voltage (such as the high voltage) may be transmitted to the control terminals of the first switch components 190 through the control line 132, so that the first switch components 190 are turned on. Since the first switch components 190 are turned on, the first common voltage lines 134 may be coupled to the first signal transmission line 130. Then, the circuit board 150 may provide the common voltage to the first signal transmission line 130 and the first common voltage lines 134. In addition, the first common electrode 180 may be coupled to one of the first common voltage lines 134 through the first vias 184.

In the sensing mode, the circuit board 150 may provide the second voltage (such as the low voltage) to the control line 132, and the second voltage (such as the low voltage) may be transmitted to the control terminals of the first switch components 190 through the control line 132, so that the first switch components 190 are turned off. Since the first switch components 190 are turned off, the first common voltage lines 134 are not coupled to the first signal transmission line 130. In addition, the sensing signal provided by the driving chip 140 may be transmitted to the first common voltage lines 134 and the second common voltage lines 162 through the connection pads 170. The first common electrode 180 and the second common electrode 182 may be used as sensing electrodes for receiving a sensing response voltage.

One of the second switch components 192 may be coupled to the second signal transmission line 160, the control line 132 and one of the second common voltage lines 162. Furthermore, each of the second switch component 192 may include a first terminal, a second terminal and a control terminal. The first terminals of the second switch components 192 may be coupled to the second signal transmission line 160. The second terminals of the second switch components 192 may be coupled to the second common voltage lines 162. The control terminals of the second switch components 192 may be coupled to the control line 132. In addition, in the display mode and the sensing mode, the operations of the second switch components 192 may be the same as or similar to the operations of the first switch components 190. Accordingly, the operations of the second switch components 192 may refer to the above description of the operations of the first switch components 190, and the description thereof is not repeated herein.

In some embodiments, each of the first switch components 190 and the second switch components 192 may be a thin film transistor (TFT), but the disclosure is not limited thereto. Furthermore, a first terminal of each of the first switch components 190 and the second switch components 192 may be a drain terminal of the thin film transistor, a second terminal of each of the first switch components 190 and the second switch components 192 may be a source terminal of the thin film transistor, and a control terminal of each of the first switch components 190 and the second switch components 192 may be a gate terminal of the thin film transistor.

In some embodiments, the electronic device 100 further includes a connection pad 194, a connection pad 196 and a connection pad 198. The connection pad 194, the connection pad 196 and the connection pad 198 may be disposed on the substrate 120, and the connection pad 194, the connection pad 196 and the connection pad 198 may at least partially overlap the circuit board 150. In addition, the first signal transmission line 130, the control line 132 and the second signal transmission line 160 may be coupled to the circuit board 150 through the connection pad 194, the connection pad 196 and the connection pad 198. That is, the first voltage and the second voltage provided by the circuit board 150 may be transmitted to the control line 132 through the connection pad 198, and the common voltage provided by the circuit board 150 may be transmitted to the first signal transmission line 130 and the second signal transmission line 160 through the connection pad 194 and the connection pad 196.

In some embodiments, in the active area 121, there is a distance D1 between the first common voltage line 134 and the second common voltage line 162. In a position adjacent to the connection pads 170, there is a distance D2 between the first common voltage line 134 and the second common voltage line 162. In the embodiment, the distance D2 may be smaller than the distance D1, but the disclosure is not limited thereto. That is, the distance between the first common voltage line 134 and the second common voltage line 162 is wider in the active area 121, and the distance between the first common voltage line 134 and the second common voltage line 162 is narrower outside the active area 121. This design may increase the space utilization of the peripheral area 122.

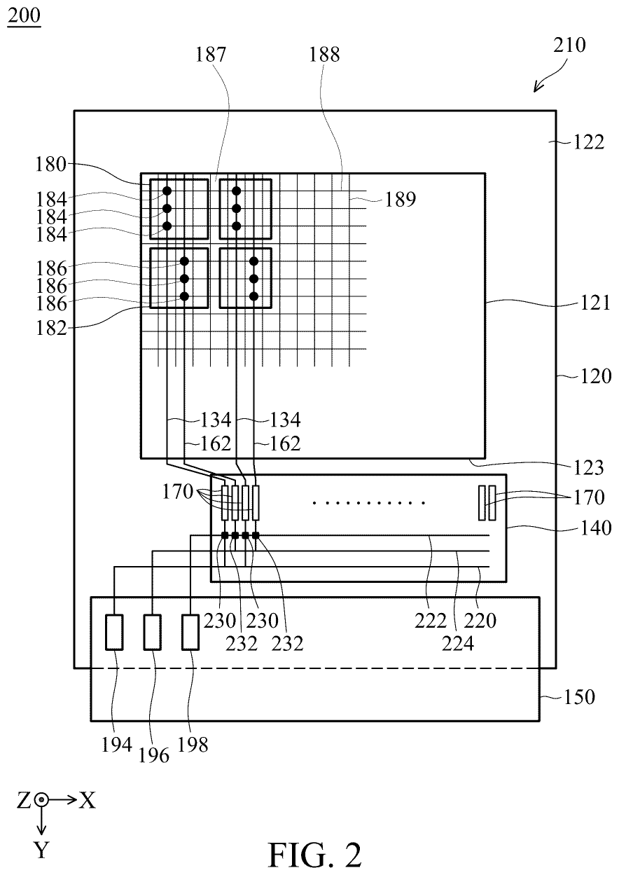

FIG. 2 is a schematic view of an electronic device according to another embodiment of the disclosure. Please refer to FIG. 2. The electronic device 200 may at least include a panel 210 and a circuit board 150. The panel 210 may at least include a substrate 120, a first signal transmission line 220, a control line 222, a plurality of first common voltage lines 134, a driving chip 140, a second signal transmission line 224, a plurality of second common voltage lines 162, a first switch component 230, a second switch component 232, a plurality of connection pads 170, a first common electrode 180, a second common electrode 182, a connection pad 194, a connection pad 196 and a connection pad 198.

The first signal transmission line 220 may be disposed in the peripheral area 122. The control line 222 may be disposed in the peripheral area 122. The second signal transmission line 224 may be disposed in the peripheral area 122. In the top view, the second signal transmission line 224 may be located between the first signal transmission line 220 and the control line 222. The circuit board 150 may be coupled to the first signal transmission line 220, the control line 222 and the second signal transmission line 224.

In the top view, the connection pads 170, the first signal transmission line 220, the control line 222 and the second signal transmission line 224 may be adjacent to the first side 123 of the active area 121, and the peripheral area 122 adjacent to the first side 123 may be a terminal side. Therefore, the space of the peripheral area 122 on the left and right sides of active area 121 in the first direction may be reduced, or a narrow edge effect may be achieved. In addition, a portion of each of the first signal transmission line 220, the control line 222 and the second signal transmission line 224 overlaps the driving chip 140.

Furthermore, one of the first switch components 230 may be coupled to the first signal transmission line 220, the control line 222 and one of the connection pads 170, and one of the second switch components 232 may be coupled to the second signal transmission line 224, the control line 222 and one of the connection pads 170. Moreover, the first switch components 230 and the second switch components 232 may overlap the driving chip 140, so as to effectively utilize the space of the electronic device 200.

In the display mode and the sensing mode, the operations of the first signal transmission line 220, the control line 222, the second signal transmission line 224, the first switch components 230 and the second switch components 232 in FIG. 2 are the same as or similar to the operations of the first signal transmission line 130, the control line 132, the second signal transmission line 160, the first switch components 190 and the second switch components 192 in FIG. 1.

In the embodiment, the first signal transmission line 220, the control line 222 and the second signal transmission line 224 are disposed adjacent to the first side 123 and are located between the connection pads 170 and the circuit board 150. Therefore, the first signal transmission line 220, the control line 222 and the second signal transmission line 224 may perform open-circuit or short-circuit testing on the fan-out area of the substrate 120, or optimize the common voltage. In addition, the fan-out area of the substrate 120 is located, for example, between the first side 123 and the connection pads 170.

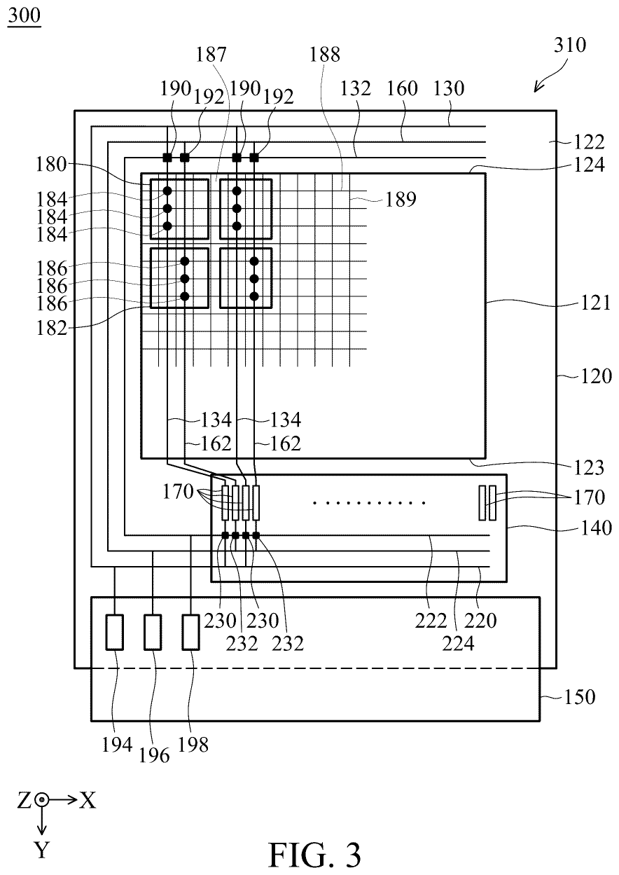

FIG. 3 is a schematic view of an electronic device according to another embodiment of the disclosure. Please refer to FIG. 3. The electronic device 300 may at least include a panel 310 and a circuit board 150.

The panel 310 may at least include a substrate 120, a first signal transmission line 130, a first signal transmission line 220, a control line 132, a control line 222, a plurality of first common voltage lines 134, a driving chip 140, a second signal transmission line 160, a second signal transmission line 224, a plurality of second common voltage lines 162, a plurality of connection pads 170, a first common electrode 180, a second common electrode 182, a connection pad 194, a connection pad 196, a connection pad 198, a plurality of first switch components 190, a plurality of first switch components 230, a plurality of second switch components 192 and a plurality of second switch components 232.

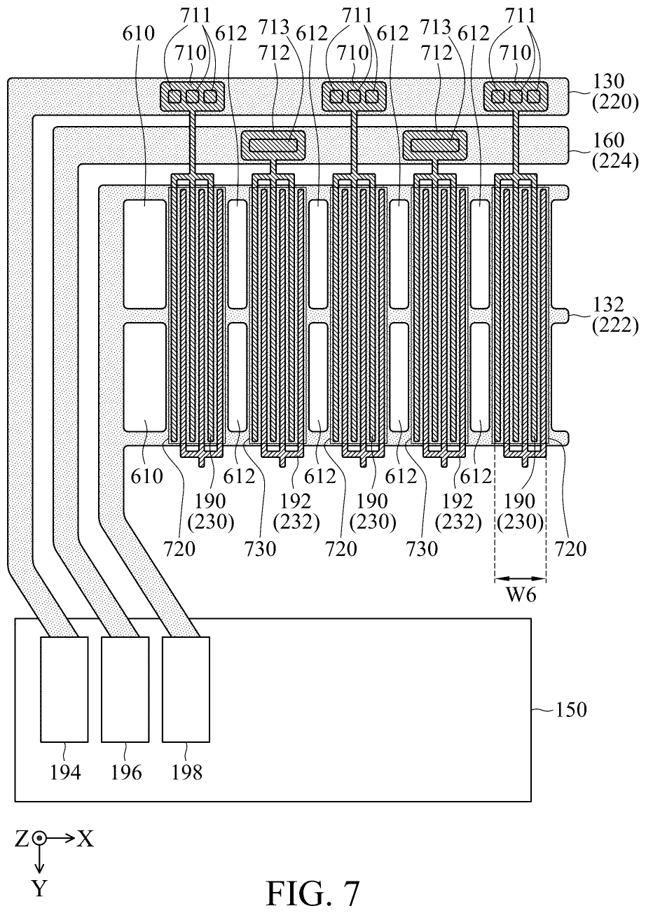

In some embodiments, the size of the first switch components 190 in the second side 124 may be greater than the size of the first switch components 230 in the first side 123. That is, the width of the first switch components 190 may be greater than the width of the first switch components 230. In the embodiment, the width W6 of the first switch components 190 and the width W6 of the first switch components 230 may be the width of the semiconductors 720 of the first switch components 190 and the first switch components 230 in the first direction, as shown in FIG. 7. In addition, the width of the second switch components 192 in the second side 124 is the same as or similar to the width W6 of the first switch components 190 in the second side, and the width of the second switch components 232 in the first side 123 is the same as or similar to the width W6 of the first switch components 230 in the first side 123. Accordingly, the width of the second switch components 192 in the second side 124 and the width of the second switch components 232 in the first side 123 may refer to the above description of the width of the first switch components 190 and the width of the first switch components 230, and the description thereof is not repeated herein.

In some embodiments, the width W6 of the first switch components 190 and the second switch components 192 adjacent to the second side 124 of the active area 121 is, for example, greater than 30 micrometers (um), but the disclosure is not limited thereto. In some embodiments, the width W6 of the first switch components 230 and the second switch components 232 adjacent to the first side 123 of the active area 121 is, for example, 5 um˜100 μm, but the disclosure is not limited thereto. In addition, in the embodiment, the driving chip 140 and the circuit board 150 are disposed in the same side (such as the first side 123 of the active area 121), so that the distance of the signal transmission is relatively short, but the disclosure is not limited thereto. In other embodiments, the driving chip 140 and the circuit board 150 may be disposed in the different sides.

Therefore, the electronic device 300 may have the functions of the electronic device 100 and the electronic device 200, i.e., the effect of signal difference of the first common voltage lines 134 and the second common voltage lines 162 may be reduced, or the display unevenness caused by the signal difference may be reduced, or the open-circuit or short-circuit testing may be performed on the fan-out area of the substrate 120.

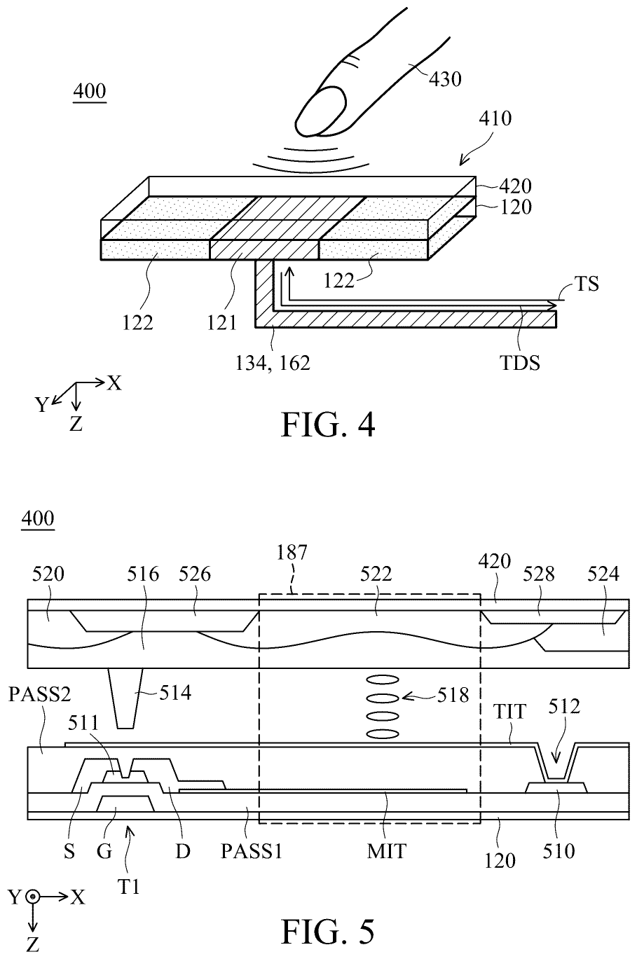

FIG. 4 is a schematic view of a structure of an electronic device according to an embodiment of the disclosure. Please refer to FIG. 4. The electronic device 400 may include a panel 410, wherein the panel 410 may be the panel 110 of FIG. 1, the panel 210 of FIG. 2, or the panel 310 of FIG. 3. The panel 410 at least include an upper substrate 420, a substrate 120, a plurality of first common voltage lines 134 and a plurality of second common voltage lines 162. The upper substrate 420 may be disposed on the substrate 120. The substrate 120 may include an active area 121 and a peripheral area 122 adjacent to (for example, surrounding) the active area 122. The first common voltage lines 134 and the second common voltage lines 162 may be disposed on the substrate 120.

At least one portion of the first common voltage lines 134 and the second common voltage lines 162 may be located in the active area 121. In the sensing mode, the first common voltage lines 134 and the second common voltage lines 162 may receive the sensing signal TS provided by the driving chip (such as the driving chip 140 of FIG. 1, FIG. 2, or FIG. 3). Then, when the object 430 touches the active area 121 of the panel 410, the active area 121 may generate a voltage change to generate a corresponding sensing response signal TDS, and the first common voltage lines 134 and the second common voltage lines 162 may transmit the above sensing response signal TDS to the driving chip (such as the driving chip 140 of FIG. 1, FIG. 2, or FIG. 3), so as to perform corresponding sensing operations.

FIG. 5 is a cross-sectional view of an active area 121 of FIG. 4. Please refer to FIG. 5. The pixel switch T1 may include a gate G, a source S, a drain D, a semiconductor 511 and an insulating layer PASS1. The insulating layer PASS1 may be disposed between the gate G, the source S, the drain D and the semiconductor 511.

In the embodiment, a portion of the pixel electrode MIT may be disposed between the insulating layer PASS1 and the insulating layer PASS2, and another portion of the pixel electrode MIT may be disposed between the insulating layer PASS1 and the drain D of the pixel switch T1 and coupled to the drain D of the pixel switch T1, but the disclosure is not limited thereto. In other embodiments, the manufacturing process sequence of the pixel electrode MIT and the drain D may be reversed. For example, a portion of the pixel electrode MIT may be disposed between the insulating layer PASS1 and the insulating layer PASS2, and another portion of the pixel electrode MIT may be disposed between the insulating layer PASS2 and the drain D of the pixel switch T1 and coupled to the drain D of the pixel switch T1.

The common electrode layer TIT may be disposed on the insulating layer PASS2. The conductive structure 510 may be disposed between the insulating layer PASS1 and the insulating layer PASS2. In addition, the insulating layer PASS2 has a via 512. The via 512 is located on the conductive structure 510, and the common electrode layer TIT may be coupled to the conductive structure 510 through the via 512. The photo spacer PS) 514 is disposed between common electrode layer TIT and the insulating (overcoat, OC) layer 516.

The modulation dielectric layer 518 is disposed between the common electrode layer TIT and the insulating layer 516. The color photoresist layer 520, the color photoresist layer 522 and the color photoresist layer 524 are disposed on the insulating layer 516. The color photoresist layer 520 and the color photoresist layer 522 do not overlap, and the color photoresist layer 522 and the color photoresist layer 524 partially overlap.

The black matrix (BM) photoresist layer 526 is disposed on the color photoresist layer 520, the insulating layer 516 and the color photoresist layer 522. The black matrix photoresist layer 528 is disposed on the color photoresist layer 522 and the color photoresist layer 524. The upper substrate 420 is disposed on the color photoresist layer 520, the black matrix photoresist layer 526, the color photoresist layer 522 and the black matrix photoresist layer 526.

In the embodiment, the common electrode layer TIT may be the first common electrode 180 or the second common electrode 182 in FIG. 1, FIG. 2 or FIG. 3, and the conductive structure 510 may be the first common voltage line 134 or the second common voltage line 162 in FIG. 1, FIG. 2 or FIG. 3, but the disclosure is not limited thereto. The insulating layer PASS1, the pixel electrode MIT, the insulating layer PASS2, the common electrode layer TIT, the modulation dielectric layer 518, the insulating layer 516 and the color photoresist layer 522 may form the pixel 187 in FIG. 1, FIG. 2 or FIG. 3.

In some embodiments, the pixel electrode MIT may choose to use a reflective electrode, a transparent electrode or a semi-transparent electrode, but the disclosure is not limited thereto.

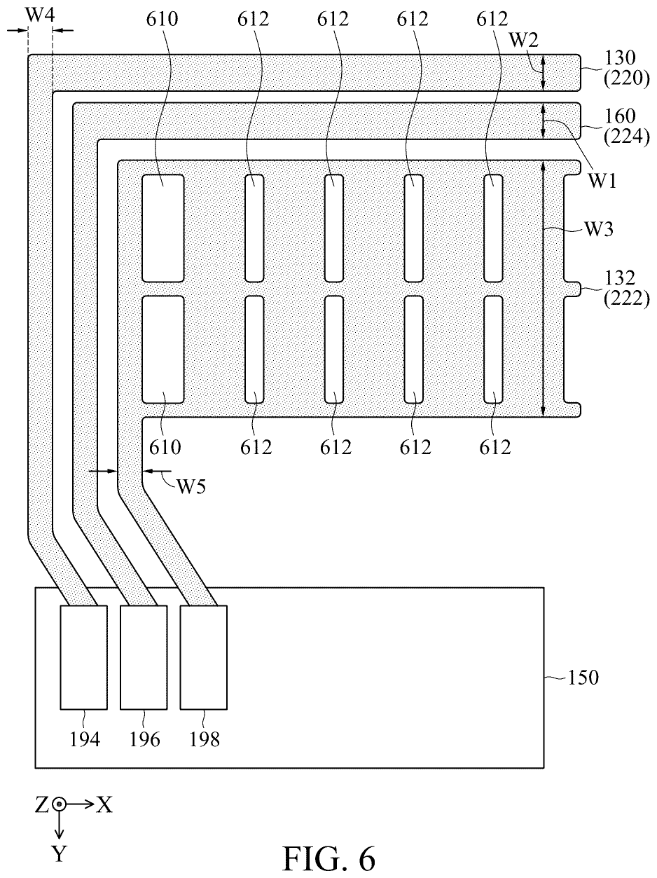

FIG. 6 is a schematic view of a line layout of a first signal transmission line, a second signal transmission line, a control line and a circuit board according to an embodiment of the disclosure. Please refer to FIG. 6. The second signal transmission line 160 (224) may be disposed between the first signal transmission line 130 (220) and the control line 132 (222). The first signal transmission line 130 (220) may be coupled to the circuit board 150 through the connection pad 194. The second signal transmission line 160 (224) may be coupled to the circuit board 150 through the connection pad 196. The control line 132 (222) may be coupled to the circuit board 150 through the connection pad 198.

In some embodiments, in the second direction, the width W2 of the second signal transmission line 160 (224) may be the same as the width W1 of the first signal transmission line 130 (220), but the disclosure is not limited thereto. In addition, in the second direction, the width W3 of a portion of the control line 132 (222) may be greater than the width W1 of the first signal transmission line 130 (220) and/or the width W2 of the second signal transmission line 160 (224), but the disclosure is not limited thereto. Furthermore, in the first direction, the width W5 of another portion of the control line 132 (222) may be equal to the width W4 of another portion of the first signal transmission line 130 (220), but the disclosure is not limited thereto. The control line 132 (222) may include a plurality of vias 610 and a plurality of vias 612. The vias 610 and the vias 612 are disposed on the control line 132 (222), so as to reduce the capacitance capacity formed by the control line 132 (222).

The vias 612 on the control line 132 (222) may be located between the first switch components 190 (230) and the second switch components 192 (232). In some embodiments, the area of the vias 612 (such as the vias between the first switch components 190 (230) and the second switch components 192 (232)) may be smaller than the area of the vias 610 (such as the leftmost via in the first direction), so that the first switch components 190 (230) and the second switch components 192 (232) may be closely arranged.

FIG. 7 is a schematic view of a line layout of a first signal transmission line, a second signal transmission line, a control line, a plurality of first switch components, a plurality of second switch components and a circuit board according to an embodiment of the disclosure. In the embodiment, the first signal transmission line 130 (220), the control line 132 (222), the second signal line 160 (224) and the circuit board 150 in FIG. 7 are the same as or similar to first signal transmission line 130 (220), the control line 132 (222), the second signal line 160 (224) and the circuit board 150 in FIG. 6. Accordingly, the first signal transmission line 130 (220), the control line 132 (222), the second signal line 160 (224) and the circuit board 150 in FIG. 7 may refer to the description of the embodiment of FIG. 6, and the description thereof is not limited thereto.

The control terminals of the first switch components 190 (230) and the second switch components 192 (232) are coupled to the control line 132 (222). In the embodiment, the control terminals of the first switch components 190 (230) and the second switch components 192 (232) may be a portion of the control line 132 (222).

A plurality of connection pads 170 may be disposed on the first signal transmission line 130 (220). The first terminals of the first switch components 190 (230) may be coupled to the connection pads 710, and each of the connection pads 710 is coupled to the first signal transmission line 130 (220) through a plurality of vias 711. In some embodiments, each of the first switch components 190 (230) may include a semiconductor 720. A plurality of connection pads 172 may be disposed on the second signal transmission line 160 (224). The first terminals of the second switch components 192 (232) may be coupled to the connection pads 712, and each of the connection pad 712 is coupled to the second transmission line 160 (224) through a via 713. In some embodiments, each of the second switch components 192 (232) may include a semiconductor 730.

In the embodiment, the sources and the drains of the first switch components 190 (230) and the second switch components 192 (232) are, for example, comb-shaped. For example, the first terminal of each of the first switch components 190 (230) coupled to the connection pads 170 is divided into three branch portions overlapping the semiconductor 720, the second terminal of each of the first switch components 190 (230) is also divided into three branch portions overlapping the semiconductor 720, the branch portions of the first terminal and the branch portions of the second terminal are stagged with each other, but the disclosure is not limited thereto. In some embodiments, the edges or turning points of the first signal transmission line 130 (220), the second signal transmission line 160 (224) and the control line 132 (222) are arc-shaped, so as to reduce the generation of static electricity.

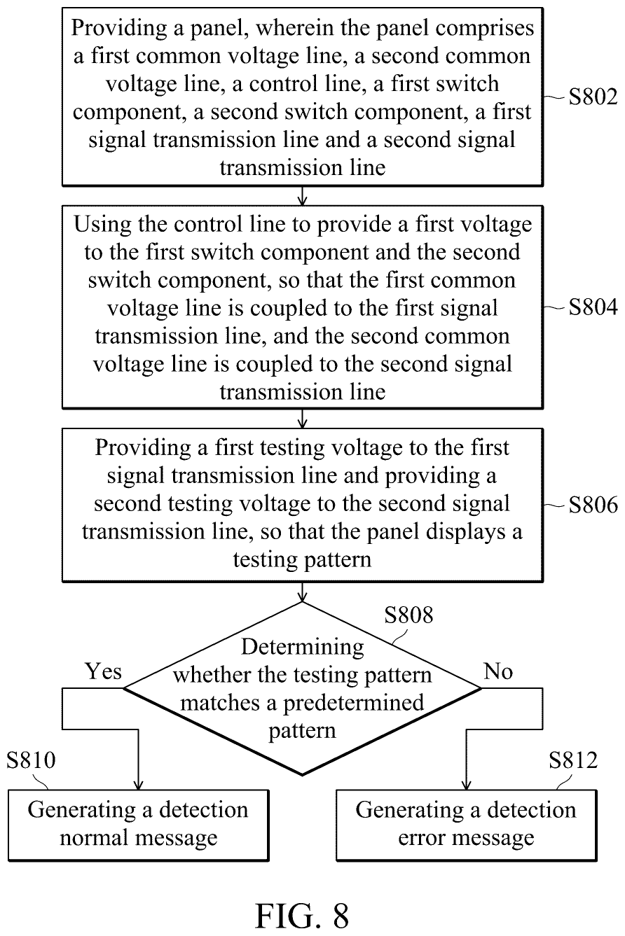

FIG. 8 is a flowchart of a detection method of an electronic device according to an embodiment of the disclosure. In step S802, the method involves providing a panel, wherein the panel comprises a first common voltage line, a second common voltage line, a control line, a first switch component, a second switch component, a first signal transmission line and a second signal transmission line. In step S804, the method involves using the control line to provide a first voltage to the first switch component and the second switch component, so that the first common voltage line is coupled to the first signal transmission line, and the second common voltage line is coupled to the second signal transmission line.

In step S806, the method involves providing a first testing voltage to the first signal transmission line and providing a second testing voltage to the second signal transmission line, so that the panel displays a testing pattern. In some embodiments, the first testing voltage is, for example, 0V, and the second testing voltage is, for example, 5V. For example, when the first testing voltage is 0V, the pixel corresponding to the first common voltage line coupled to the first signal transmission line (corresponding to the first common electrode 180) may display black, and when the second testing voltage is 5V, the pixel corresponding to the second common voltage line coupled to the second transmission line (corresponding to the second common electrode 182) may display white, but the disclosure is not limited thereto. Therefore, when the state of the panel is normal, the testing pattern displayed on the panel is, for example, a black and white checkerboard pattern.

In step S808, the method involves determining whether the testing pattern matches a predetermined pattern. In some embodiments, the predetermined pattern may be a black and white checkerboard pattern, but the disclosure is not limited thereto. When determining that the testing pattern matches the predetermined pattern, the method performs step S810. In step S810, the method involves generating a detection normal message, and it indicates that the state of the panel is normal and does not occur the short-circuit phenomenon. When determining that the testing pattern does not match the predetermined pattern, the method performs step S812, the method involves generating a detection error message, and it indicates that the state of the panel is abnormal and occurs the short-circuit phenomenon.

In the embodiment, the detection method of the electronic device may be performed before the driving chip is disposed on the panel, which may reduce the related waste of consumables, or may determine the image sticking phenomenon of the panel in advance, or reduce the occurrence of abnormal sensing function due to short-circuit during the sensing mode after the driving chip is disposed. In other embodiments, after the electronic device is tested as above and the driving chip is disposed on the panel, the first common voltage lines, the second common voltage lines, the control line, the first signal transmission line and the second signal transmission line may be retained, so as to optimize the display effect of the electronic device during the display mode.

In summary, according to the electronic device disclosed by the embodiments of the disclosure, the first signal transmission is disposed in the peripheral area of the substrate. The control line is disposed in the peripheral area of the substrate. At least one portion of the first common voltage lines is disposed in the active area of the substrate. In the display mode, the circuit board provides the first voltage to the control line, so that the first common voltage lines are coupled to the first signal transmission line. In the sensing mode, the driving chip provides the sensing signal to the first common voltage lines, the circuit board provides the second voltage to the control line, so that the first common voltage lines are not coupled to the first signal transmission line. Therefore, the effect of signal difference of the first common voltage lines may be reduced, or the display unevenness caused by the signal difference may be reduced.

In addition, the electronic device of the disclosure further includes the second signal transmission line and the second common voltage lines. The second signal transmission line is disposed in the peripheral area and coupled to the circuit board. The second common voltage lines are disposed in the active area. In the display mode, the second common voltage lines are coupled to the second signal transmission line. In the sensing mode, the second common voltage lines are not coupled to the second signal transmission line. Therefore, the effect of signal difference of the first common voltage lines and the second common voltage lines may be reduced, or the display unevenness caused by the signal difference may be reduced.

Furthermore, the electronic device of the disclosure may further dispose the connection pads, the first signal transmission line, the second signal transmission line and the control line adjacent the first side of the active area. Therefore, it may perform the open-circuit or short-circuit testing on the fan-out area of the substrate, or optimize the common voltage.

Moreover, according to the detection method of the electronic device disclosed by the embodiments of the disclosure, the first voltage is provided to the control line, so that the first common voltage line is coupled to the first signal transmission line, and the second common voltage line is coupled to the second signal transmission line. The first testing voltage is provided to the first signal transmission line and the second testing voltage is provided to the second signal transmission line, so that the panel displays the testing pattern. It is determined whether the testing pattern matches the predetermined pattern, so as to generate the detection normal message or the detection error message. Therefore, it may reduce the related waste of consumables, or may determine the image sticking phenomenon of the panel in advance, or reduce the occurrence of abnormal sensing function due to short-circuit during the sensing mode after the driving chip is disposed.

While the disclosure has been described by way of example and in terms of the preferred embodiments, it should be understood that the disclosure is not limited to the disclosed embodiments. On the contrary, it is intended to cover various modifications, combinations, and similar arrangements (as would be apparent to those skilled in the art). Therefore, the scope of the appended claims should be accorded the broadest interpretation to encompass all such modifications, combinations, and similar arrangements.

What is claimed is:

1. An electronic device, having a display mode and a sensing mode, wherein the electronic device comprises:
a panel, comprising:
a substrate, comprising an active area and a peripheral area surrounding the active area;
a first signal transmission line, disposed in the peripheral area;
a control line, disposed in the peripheral area;
a plurality of first common voltage lines, disposed in the active area;
a plurality of first switch components, coupled between the plurality of first common voltage lines and the first signal transmission line; and
a driving chip, coupled to the plurality of first common voltage lines; and
a circuit panel, coupled to the control line,
wherein in the display mode, the circuit board provides a first voltage to the plurality of first switch components through the control line, so that the plurality of first common voltage lines are coupled to the first signal transmission line,
wherein in the sensing mode, the driving chip provides a sensing signal to the plurality of first common voltage lines, and the circuit board provides a second voltage to the plurality of first switch components through the control line, so that the plurality of first common voltage lines are not coupled to the first signal transmission line.

2. The electronic device according to claim 1, wherein the panel further comprises a second signal transmission line and a plurality of second common voltage lines, the second signal transmission line is disposed in the peripheral area and coupled to the circuit board, and the plurality of second common voltage lines are disposed in the active area.

3. The electronic device according to claim 2, wherein in a top view, one of the plurality of second common voltage lines is located between two of the plurality of first common voltage lines adjacent to each other.

4. The electronic device according to claim 2, wherein in the display mode, the plurality of second common voltage lines are coupled to the second signal transmission line, and in the sensing mode, the plurality of second common voltage lines are not coupled to the second transmission line.

5. The electronic device according to claim 2, wherein the panel further comprises a plurality of connection pads disposed on the substrate, and the plurality of first common voltage lines and the plurality of second common voltage lines are coupled to the driving chip through the connection pads.

6. The electronic device according to claim 5, wherein in a top view, the plurality of connection pads, the first signal transmission line, the second signal transmission line and the control line are adjacent to a first side of the active area.

7. The electronic device according to claim 6, wherein a portion of each of the first signal transmission line, the second signal transmission line and the control line overlaps with the driving chip.

8. The electronic device according to claim 5, wherein in a top view, the plurality of connection pads are adjacent to a first side of the active area, the first signal transmission line, the second signal transmission line and the control line are adjacent to a second side of the active area, and the first side is opposite to the first side of the active area.

9. The electronic device according to claim 8, wherein the driving chip is located between the first side of the active area and the circuit board.

10. The electronic device according to claim 2, wherein the panel further comprises a first common electrode and a second common electrode, the first common electrode is adjacent to the second common electrode, the first common electrode is coupled to one of the plurality of first common voltage lines through a plurality of first vias, and the second common electrode is coupled to one of the plurality of second common voltages through a plurality of second vias.

11. The electronic device according to claim 2, wherein the panel further comprises a plurality of second switch components, and the plurality of second switch components are coupled between the plurality of second common voltage lines and the second signal transmission line.

12. The electronic device according to claim 2, wherein the panel further comprises a plurality of connection pads disposed on the substrate, and the plurality of connection pads at least partially overlap the circuit board.

13. The electronic device according to claim 12, wherein the first signal transmission line, the control line and the second signal transmission line are coupled to the circuit board through the plurality of connection pads.

14. The electronic device according to claim 2, wherein a width of the second signal transmission line is the same as a width of the first signal transmission line.

15. The electronic device according to claim 2, wherein a width of a portion of the control line is greater than a width of the first signal transmission line and/or a width of the second signal transmission line.

16. The electronic device according to claim 2, wherein a width of a portion of the control line is equal to a width of a portion of the first signal transmission line.

17. The electronic device according to claim 2, wherein the control line comprises a plurality of first vias and a plurality of second vias.

18. The electronic device according to claim 17, wherein the plurality of second vias of the control line are located between the plurality of first switch components and the plurality of second switch components, and areas of the plurality of second vias are smaller than areas of the plurality of first vias.

19. A detection method of an electronic device, comprising:
providing a panel, wherein the panel comprises a first common voltage line, a second common voltage line, a control line, a first switch component, a second switch component, a first signal transmission line and a second signal transmission line;
using the control line to provide a first voltage to the first switch component and the second switch component, so that the first common voltage line is coupled to the first signal transmission line, and the second common voltage line is coupled to the second signal transmission line;
providing a first testing voltage to the first signal transmission line and providing a second testing voltage to the second signal transmission line, so that the panel displays a testing pattern;
determining whether the testing pattern matches a predetermined pattern;
when determining that the testing pattern matches the predetermined pattern, generating a detection normal message; and
when determining that the testing pattern does not match the predetermined pattern, generating a detection error message.

20. The detection method of the electronic device according to claim 12, wherein the panel further comprises a first common electrode and a second common electrode, the first common electrode is adjacent to the second common electrode, the first common electrode is coupled to the first common voltage line through a plurality of first vias, and the second common electrode is coupled to the second common voltage through a plurality of second vias.
